(19) United States
(12) Patent Application Publication
(10) Pub. No.: US 2025/0280602 A1
(43) Pub. Date: Sep. 4, 2025

(54) STRETCHABLE DISPLAY DEVICE

(71) Applicant: LG Display Co., Ltd., Seoul (KR)

(72) Inventors: Yu-Ra JEONG, Paju-si (KR); Hae-Yoon JUNG, Paju-si (KR); Hyo-Kang LEE, Paju-si (KR); Ae-Sun KIM, Paju-si (KR); Myung-Sub LIM, Paju-si (KR); In-Jun LEE, Paju-si (KR)

(21) Appl. No.: 18/915,928

(22) Filed: Oct. 15, 2024

(30) Foreign Application Priority Data
Feb. 29, 2024 (KR) 10-2024-0029399

(51) Int. Cl. H01L 27/12; H01L 25/075; H01L 25/16

(52) U.S. Cl. CPC H10D 86/60; H01L 25/0753; H01L 25/167; H10D 86/441

(57) ABSTRACT

A stretchable display device includes a first substrate including a display area and a non-display area. A plurality of rigid portions are provided in the display area and spaced apart from each other in a first direction and a second direction and a soft portion is provided between adjacent rigid portions. A link area is in the non-display area and a plurality of link lines are in the link area. A second substrate is disposed over the first substrate. At least one link line includes a high resistance link and a low resistance link with each of the high resistance link and the low resistance link including at least one curved part and at least one straight part. A ratio of length to straight line of the high resistance link is greater than a ratio of length to straight line of the low resistance link.

### CROSS-REFERENCE TO RELATED APPLICATION

The present application claims priority to Korean Patent Application No. 10-2024-0029399 filed in the Republic of Korea on Feb. 29, 2024, the entire contents of which are hereby expressly incorporated by reference into the present application.

### BACKGROUND

### Technical Field

The present disclosure relates to a display device, and more particularly, but not exclusively, to a stretchable display device.

### Description of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been studied.

Recently, a stretchable display device, which is much more flexible than the above example flexible display devices, has received consideration as a next-generation display.

A stretchable display device is a display that can freely transform the shape of a screen without distortion even when the size of the screen is increased, folded, or twisted. Unlike bendable, foldable, or rollable display devices that can only be transformed in a specific area or direction, stretchable display devices are able to implement free-form transformation and are considered as the most suitable display for the era of the Internet of Things (IoT), 5G, and autonomous vehicles. Despite the potential benefits of stretchable display devices, there have been substantial challenges with their implementation and there are currently a number of deficiencies and drawbacks with current stretchable display device solutions.

For example, a stretchable display device may include pixels and a link line connecting the pixels to a driver circuit. The location of the pixels and pads on the driver circuit may result in a length of the link lines changing based on their location. Due to the difference in length, the link lines may have different resistances, and as a result, the signals transmitted through the link lines are not uniform, resulting in a problem of deteriorating image quality. Accordingly, it would be advantageous to have a stretchable display device that overcomes these and other deficiencies and disadvantages of current solutions.

### BRIEF SUMMARY

Accordingly, the present disclosure provides a stretchable display device that substantially obviates one or more of the limitations and disadvantages described above and associated with the current state of the art.

More specifically, one or more embodiments of the present disclosure provide a stretchable display device capable of implementing uniform image quality by compensating for resistance deviation that result from differences in length of the link lines.

One or more embodiments of the present disclosure also provide a stretchable display device capable of improving durability.

In one or more embodiments of the disclosure, a stretchable display device may include a rigid portion in which a pixel is disposed and a soft portion in which a connection line connecting the pixels is disposed. The rigid portion may not be stretched, and the soft portion may be stretched.

The pixel provided in the rigid portion may be connected to a driver circuit through a link line to receive a signal. Since a pixel pitch and a pad pitch are different from each other, a length of the link line connecting the pixel and a pad of the driver circuit may vary depending on its location.

To achieve these and other aspects of the present disclosure, as embodied and broadly described herein, a stretchable display device may include: a first substrate including a display area and a non-display area; a plurality of rigid portions provided in the display area on the first substrate and spaced apart from each other in a first direction and a second direction; a soft portion provided between adjacent rigid portions in the first direction or the second direction; a link area provided in the non-display area on the first substrate; a plurality of link lines provided in the link area; and a second substrate disposed over the first substrate, wherein at least one link line of the plurality of link lines includes a high resistance link and a low resistance link, wherein each of the high resistance link and the low resistance link includes at least one curved part and at least one straight part, and wherein a ratio of length to straight line of the high resistance link is greater than a ratio of length to straight line of the low resistance link.

Additional features and aspects will be set forth in the description that follows, and will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

It is to be understood that both the foregoing background description and the following detailed description provide example embodiments that are intended to provide further explanation of the inventive concepts and techniques of the disclosure, but are not intended to limit the scope of the disclosure or the appended claims.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic perspective view of a stretchable display device according to an embodiment of the present disclosure;

FIG. 2 is a plan view schematically illustrating a rigid portion and a flexible portion of the stretchable display device of FIG. 1;

FIG. 3 is an equivalent circuit diagram for a sub-pixel of the stretchable display device of FIG. 1;

FIG. 4 is a cross-sectional view of the rigid portion and the flexible portion of FIG. 2 along line I-I′ of FIG. 2;

FIG. 5 is a schematic plan view of a stretchable display device according to an embodiment of the present disclosure;

FIG. 6 is a schematic plan view of area B1 of FIG. 5;

FIG. 7 is a schematic plan view of area B2 of FIG. 5;

FIG. 8 is a schematic plan view of area B3 of FIG. 5;

FIG. 9 is a schematic plan view of a stretchable display device according to an embodiment of the present disclosure;

FIG. 10 is a schematic view of a structure of a high resistance link of a link line according to an embodiment of the present disclosure;

FIG. 11 is a schematic view of a structure of a low resistance link of a link line according to an embodiment of the present disclosure;

FIG. 12 is a schematic plan view of a link area of a stretchable display device according to an embodiment of the present disclosure;

FIG. 13 is a cross-sectional view of the link area of FIG. 12 along line II-II′ of FIG. 12;

FIG. 14 is a cross-sectional view of the link area of FIG. 12 along line III-III′ of FIG. 12;

FIG. 15 is a schematic plan view of a link area of a stretchable display area according to an embodiment of the present disclosure; and

FIG. 16 is a cross-sectional view of the link area of FIG. 15 along line IV-IV′ of FIG. 15.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure, unless otherwise noted. Further, in the following description of the present disclosure, when a detailed description of a known related art is determined to unnecessarily obscure the concepts of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, the component being plural is included unless otherwise specified.

In analyzing a component, an error range is interpreted as being included even when there is no explicit description. Except as otherwise noted, the error range may be plus or minus 5% of the stated characteristic of the component. The use of the terms “substantially” or “approximately” is interpreted to include or refer to this error range, except as otherwise defined herein.

In describing a positional relationship, for example, when a positional relationship of two parts and/or layers is described as being “over,” “on,” “above,” “below,” “under,” “next to,” or the like, one or more other parts and/or layers can be provided between the two parts and/or layers, unless the term “immediately” or “directly” is used therewith, in which case, there are no intervening parts and/or layers between the two parts and/or layers.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, or may be used separately from each other. As a result, technically various interlocking and driving configurations are possible, and each of the embodiments can be independently implemented with respect to each other or implemented together in a related relationship. Further, embodiments of the disclosure include singular aspects of the described embodiments as well as the singular aspects combined with one or more other aspects.

Hereinafter, embodiments of the present disclosure will be described in detail with reference to accompanying drawings.

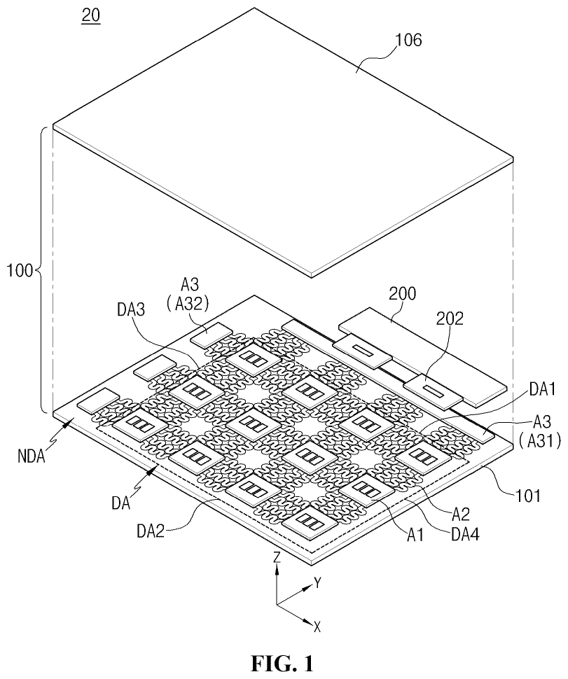

FIG. 1 is a schematic perspective view of a stretchable display device 20 according to an embodiment of the present disclosure.

In FIG. 1, the stretchable display device 20 may include a display panel 100, a printed circuit board 200, and a flexible printed circuit 202.

The display panel 100 may be stretched in a first direction X and/or a second direction Y and/or a third direction Z. The display panel 100 may include a first substrate 101 and a second substrate 106 disposed on the first substrate 101. The first substrate 101 includes a display area DA displaying an image or configured to display an image and a non-display area NDA provided on and surrounding at least one side of the display area DA. The non-display area NDA may not display images or may not be configured to display images.

The display area DA of the first substrate 101 may include a rigid portion A1 corresponding to a first area of the display area DA and a soft portion A2 (which may also be referred to herein as a flexible portion A2) corresponding to a second area of the display area DA. The non-display area NDA of the first substrate 101 may include a pad portion A3 corresponding to a third area. Except as otherwise noted, each of the first, second, and third areas are distinct and separate sections or regions of the respective display area DA and non-display area NDA.

The rigid portion A1 may be provided in the form of an island, and a plurality of rigid portions A1 may be disposed to be spaced apart from each other along the first direction X and the second direction Y. The rigid portions A1 may be disposed in a matrix form.

For example, the rigid portion A1 may have a polygonal shape, and may have a substantially rectangular shape of rigid material.

A pixel including a plurality of sub-pixels may be provided in or on the rigid portion A1. Each of the plurality of sub-pixels may include a light-emitting diode, at least one thin film transistor, a plurality of lines, and a plurality of electrodes.

The soft portion A2 may be disposed between the rigid portions A1 adjacent to each other in each of the first direction X and the second direction Y. Multiple soft portions A2 may be provided between the adjacent rigid portions A1. In addition, the soft portion A2 may be disposed between the rigid portion A1 and the pad portion A3 (e.g., the second pad portion A32) adjacent to each other in the first direction X and between the rigid portion A1 and the pad portion A3 (e.g., the first pad portion A31) adjacent to each other in the second direction Y. As shown in FIG. 1, the soft or flexible portions A2 generally connect the rigid portions A1 to each other and also connect the rigid portions A1 to the pad portion(s) A3.

A stretchable line that is a connection line or electrical connection line connecting the adjacent pixels may be provided in the soft portion A2. The stretchable line may include a plurality of voltage lines such as a gate line, a data line, a high potential line, a low potential line, an emission line, and a reference voltage line. As used herein, the term “line” should be construed broadly to include any device capable of transmitting electricity.

The stretchable line may have at least one curved shape. For example, the stretchable line may have a wave structure of alternating vertices in opposite directions or repeating peaks and valleys.

Meanwhile, the non-display area NDA may be an area in which an image is not displayed, and the pad portion A3 may be disposed in the non-display area NDA. A plurality of link lines extending from the plurality of voltage lines disposed in the display area DA and a plurality of bonding pads connected to ends of the plurality of link lines may be provided in the pad portion A3. Each of the plurality of the link line may include a high resistance link and a low resistance link, and by differently configuring the high resistance links and the low resistance links of the adjacent link lines, the plurality of link lines may have a uniform resistance, thereby transmitting a uniform signal. These concepts are discussed further in the following description.

The pad portion A3 may include a first pad portion A31 and a second pad portion A32. The first pad portion A31 may correspond to the rigid portions A1 arranged in the first direction X, and the second pad portion A32 may correspond to the rigid portions A1 arranged in the second direction Y. The first pad portion A31 may be disposed on at least one of upper and lower sides DA1, DA2 of the display area DA, and the second pad portion A32 may be disposed on at least one of left and right sides DA3, DA4 of the display area DA. For example, as shown in FIG. 1, the first pad portion A31 may be disposed on the upper side DA1 of the display area DA, and the second pad portion A32 may be disposed on the left side DA3 of the display area DA.

The first pad portion A31 may be provided as one pattern corresponding to the plurality of rigid portions A1 arranged in the first direction X. That is, the first pad portion A31 configured as one rigid pattern may correspond to the plurality of rigid portions A1. In other words, in an embodiment, the first pad portion A31 is a singular structure corresponding to the plurality of rigid portions A1.

On the other hand, the second pad portion A32 may be separated to correspond to each of the plurality of rigid portions A1 arranged in the second direction Y. That is, the second pad portions A32 configured as a plurality of rigid patterns that may correspond to the plurality of rigid portions A1, respectively, with the second pad portions A32 spaced from each by a selected distance or in a selected arrangement in the second direction Y.

However, embodiments of the present disclosure are not limited thereto. In other embodiments, the first pad portion A31 may be separated and include multiple component parts to correspond to each of the plurality of rigid portions A1 arranged in the first direction X, and the second pad portion A32 may be provided as one pattern or a singular structure corresponding to the plurality of rigid portions A1 arranged in the second direction Y.

The rigid portion A1 and the pad portion A3 may not be stretched, and the soft portion A2 may be stretched. In some embodiments, a “rigid portion” refers to a component that is inelastic, meaning that it is stretchable by an amount equal to less than 5% of its total length or width before plastic deformation occurs. A “soft portion” or a “flexible portion” refers to a component that is elastic and may be stretched by an amount equal to greater than 5% of its total length or width without plastic deformation. Except as otherwise noted, “soft” and “flexible” may be used interchangeably and generally have the same meaning herein.

Meanwhile, the flexible printed circuit 202 may be connected to the first pad portion A31 of the pad portion A3. The flexible printed circuit 202 may include a base film made of a flexible material and a driver integrated circuit chip (driver IC chip) mounted on the base film. The flexible printed circuit 202 may generate a gate signal and a data signal for displaying the image and transmit the gate signal and the data signal to the display panel 100.

In the embodiment of FIG. 1, the flexible printed circuit 202 is shown to be a chip on film (COF) type, but embodiments of the present disclosure are not limited thereto. In other embodiments, the flexible printed circuit 202 may be a chip on glass (COG) type or a tape carrier package (TCP) type, among other possibilities.

The printed circuit board 200 may include a circuit part for controlling the driver IC chip. For example, the printed circuit board 200 may include a timing controller receiving an image signal and a plurality of timing signals, generating a plurality of control signals, and transmitting the generated control signals to the driver IC chip.

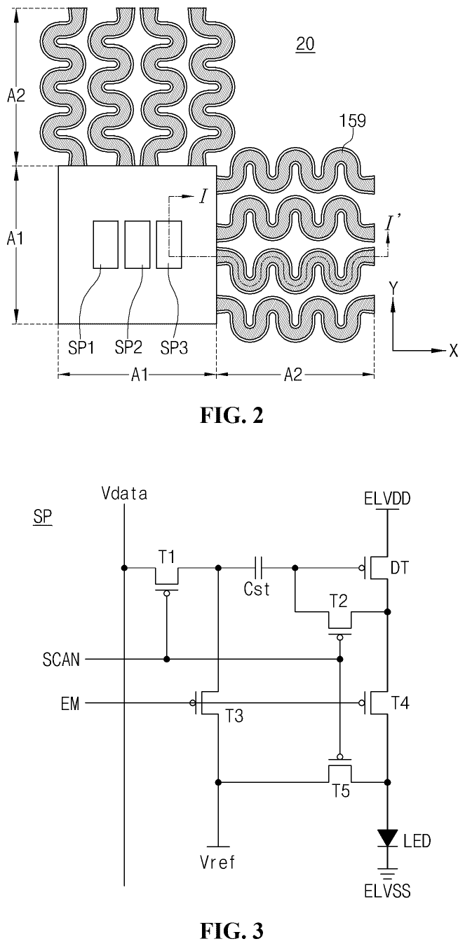

The display area DA of the stretchable display device of the present disclosure will be described in detail with reference to FIG. 2.

FIG. 2 is a plan view schematically illustrating the rigid portion A1 and the flexible portion A2 of the stretchable display device 20.

In FIG. 2, the stretchable display device 20 according to the embodiment of the present disclosure may include the rigid portion A1 and the soft portion A2 or flexible portion A2 in the display area DA.

In the rigid portion A1, the plurality of sub-pixels SP1, SP2, and SP3 may be provided on a substrate of a rigid material. For example, first, second, and third sub-pixels SP1, SP2, and SP3 may be provided in the rigid portion A1, and the first, second, and third sub-pixels SP1, SP2, and SP3 may be red, green, and blue sub-pixels.

Each of the first, second, and third sub-pixels SP1, SP2, and SP3 may include a light-emitting element, at least one transistor, and at least one capacitor.

In the soft portion A2, a stretchable or flexible line 159 may be provided. The stretchable line 159 may include at least one curved part. For example, the stretchable line 159 may have a wave structure and may include a plurality of wave shapes of repeated crests and troughs. In an embodiment, the wavelength (i.e., distance between successive crests or successive troughs) is equidistant across the stretchable line 159, or may be different or may vary along the stretchable line. Four stretchable lines 159 may be disposed between the adjacent or successive rigid portions A1. Two stretchable lines 159 may be disposed symmetrically with other two stretchable lines 159.

However, embodiments of the present disclosure are not limited thereto. The stretchable line 159 may have various structures. For example, in other embodiments, the stretchable line 159 may have an omega structure in which two omega shapes are connected to each other, among other possibilities.

The configuration of the sub-pixel provided in the rigid portion A1 of the stretchable display device of the present disclosure will be described in detail with reference to FIG. 3.

FIG. 3 is an equivalent circuit diagram for a representative sub-pixel SP of the stretchable display device 20.

In FIG. 3, one sub-pixel of the stretchable display device according to the embodiment of the present disclosure, that is, each of the first, second, and third sub-pixels SP1, SP2, and SP3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the scan signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the scan signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 3, as an example, each sub-pixel has a 6T1C structure including six transistors and one capacitor, but in other embodiments, each sub-pixel may have one of 2T1C, 4T1C, 5T1C, 3T2C, 4T2C, 5T2C, 6T2C, 7TIC, 7T2C, 8T1C, and 8T2C structures, among other possibilities.

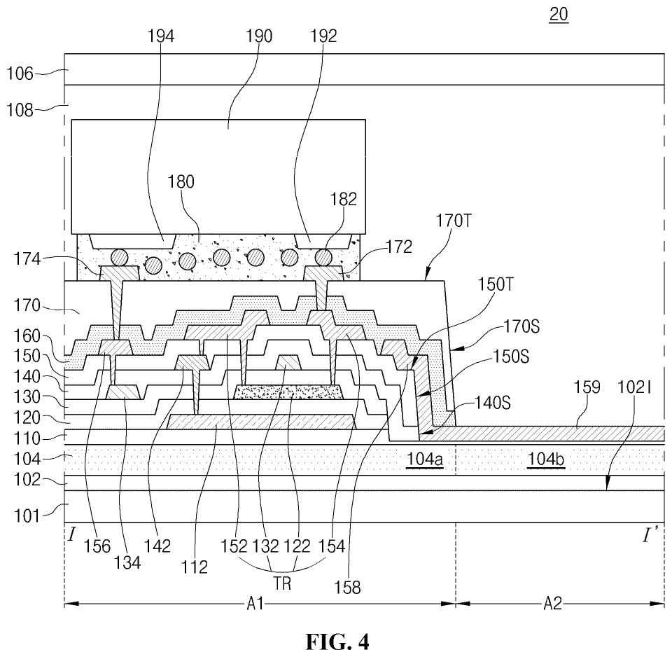

A cross-sectional structure of one or more embodiments of the stretchable display device 20 of the present disclosure will be described in detail with reference to FIG. 4.

FIG. 4 is a cross-sectional view corresponding to line I-I′ of FIG. 2. FIG. 4 shows a cross-section corresponding to one sub-pixel of the stretchable display device 20 according to an embodiment of the present disclosure and will be described with continuing reference to FIGS. 1 to 3.

In FIG. 4, the stretchable display device 20 may include the first substrate 101 and the second substrate 106 facing and spaced apart from each other on opposite sides of the display device 20.

The first substrate 101 and the second substrate 106, which are flexible substrates, may be formed of a soft matter or soft material with bending or stretching properties. For example, the first substrate 101 and the second substrate 106 may be formed of silicone rubber such as polydimethylsiloxane (PDMS), elastomer such as polyurethane (PU), or styrene butadiene block copolymer such as styrene butadiene styrene (SBS), among others.

The first substrate 101 and the second substrate 106 may be formed of the same material. However, embodiments of the present disclosure are not limited thereto. In other embodiments, the first substrate 101 and the second substrate 106 may be formed of different materials.

The first substrate 101 and the second substrate 106 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first substrate 101 and the second substrate 106 may have the elastic modulus of several MPa (i.e., 10 MPa, or more or less) to hundreds of MPa (100 or more MPa) and the ductile breaking rate of about 100% or more. In addition, each of the first substrate 101 and the second substrate 106 may have a thickness of about 10 μm to about 1 mm. However, embodiments of the present disclosure are not limited thereto.

The rigid portion A1 corresponding to the first area and the soft portion A2 corresponding to the second area may be provided on both the first substrate 101 and the second substrate 106.

A first adhesive layer 102 may be provided on an inner or top surface 1021 of the first substrate 101, and a base substrate 104 may be provided on the first adhesive layer 102.

The first adhesive layer 102 may attach the first substrate 101 and the base substrate 104. The first adhesive layer 102 may be formed of an acryl-based, silicon-based, or urethane-based adhesive, among others. For example, the first adhesive layer 102 may be optically clear adhesive (OCA) that is formed and attached in the form of a film or optically clear resin (OCR) that is cured after applying a liquid material.

The base substrate 104 may include a first base portion 104a and a second base portion 104b. The first base portion 104a may be disposed to correspond to the rigid portion A1 in the first area, and the second base portion 104b may be disposed to correspond to the soft portion A2 in the second area.

The first base portion 104a may be provided in a plate shape in the display area DA and may serve to support and protect components of the plurality of sub-pixels SP1, SP2, and SP3. The first base portion 104a may be plural components, and the plurality of first base portions 104a may be spaced apart from each other in the first direction X and the second direction Y.

The second base portion 104b may be provided between the first base portions 104a adjacent to each other in the display area DA. The second base portion 104b may include at least one curved part and may serve to support and protect a stretchable line 159. In an embodiment, a shape of the second base portion 104b corresponds to a shape of the stretchable line 159.

The first and second base portions 104a and 104b may be connected to each other and may be provided as one body in a single, unitary, integral component. The first and second base portions 104a and 104b may also be separate components coupled together.

The base substrate 104 may be formed of a rigid material having lower flexibility than the soft material of the first substrate 101. For example, the base substrate 104 may be formed of a polyimide (PI) resin or epoxy resin, among others.

The base substrate 104 may have relatively high elastic modulus, and the elastic modulus of the base substrate 104 may be higher than the elastic modulus of the first substrate 101. For example, the elastic modulus of the base substrate 104 may be more than 1,000 times higher than the elastic modulus of the first substrate 101, but embodiments of the present disclosure are not limited thereto.

A first buffer layer 110 may be provided on the base substrate 104. The first buffer layer 110 may block permeation of moisture or oxygen from the outside to protect the components of the plurality of sub-pixels SP1, SP2, and SP3.

The first buffer layer 110 may be formed as a single layer or multiple layers of an inorganic insulating material. The inorganic insulating material of the first buffer layer 110 may include silicon nitride (SiNx), silicon oxide (SiOx), or silicon oxynitride (SiON), among others.

In order to prevent damage of or to the first buffer layer 110 such as cracks due to stretching, a majority of the first buffer layer 110 may be removed in the soft portion A2 or a majority of the first buffer layer 100 may be absent from the soft portion A2 to substantially correspond to the rigid portion A1 and may be disposed over the first base portion 104a of the base substrate 104. Meanwhile, to control the thickness and hardness of the soft portion A2, the first buffer layer 110 may be partially provided with a relatively thin thickness over the second base portion 104b. In an embodiment, a thickness of the first buffer layer 110 in the soft portion A2 may be less than 25% of a thickness of the first buffer layer 110 in the rigid portion A1.

In other embodiments, the first buffer layer 110 may be omitted.

A light blocking layer 112 may be provided on the first buffer layer 110 of the rigid portion A1. The light blocking layer 112 may be formed of a conductive material such as metal. For example, the light blocking layer 112 may be formed of at least one of aluminum (Al), copper (Cu), molybdenum (Mo), titanium (Ti), chromium (Cr), nickel (Ni), tungsten (W), or an alloy thereof, among others. The light blocking layer 112 may have a single-layered structure or a multiple-layered structure.

A second buffer layer 120 may be provided on the light blocking layer 112. The second buffer layer 120 may be formed as a single layer or multiple layers of an inorganic insulating material. The inorganic insulating material of the second buffer layer 120 may include silicon nitride (SiNx), silicon oxide (SiOx), or silicon oxynitride (SiON), among others.

In order to prevent damage of the second buffer layer 120 such as cracks due to stretching, the second buffer layer 120 may be removed in the soft portion A2 to substantially correspond to the rigid portion A1. The second buffer layer 120 may be provided only over the first base portion 104a of the base substrate 104 and may not be provided over the second base portion 104b.

A semiconductor layer 122 may be provided on the second buffer layer 120 of the rigid portion A1. The semiconductor layer 122 may overlap the light blocking layer 112, and the light blocking layer 112 may block light incident on the semiconductor layer 122 and prevent the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 130 may be provided on the semiconductor layer 122. The gate insulation layer 130 may be formed as a single layer or multiple layers of an inorganic insulating material. The inorganic insulating material of the gate insulation layer 130 may include silicon nitride (SiNx), silicon oxide (SiOx), or silicon oxynitride (SiON), among others.

In order to prevent damage of the gate insulation layer 130 such as cracks due to stretching, the gate insulation layer 130 may be removed in the soft portion A2 to substantially correspond to the rigid portion A1. The gate insulation layer 130 may be provided only over the first base portion 104a of the base substrate 104 and may not be provided over the second base portion 104b.

A gate electrode 132 and a first pad 134 may be provided on the gate insulation layer 130 of the rigid portion A1.

The gate electrode 132 may overlap the semiconductor layer 122 and may be disposed to correspond to the central part of the semiconductor layer 122. Accordingly, the gate electrode 132 may also overlap the light blocking layer 112.

The first pad 134 may be spaced apart from the semiconductor layer 122 and the light blocking layer 112.

The gate electrode 132 and the first pad 134 may be formed of a conductive material such as metal. For example, the gate electrode 132 and the first pad 134 may be formed of at least one of aluminum (Al), copper (Cu), molybdenum (Mo), titanium (Ti), chromium (Cr), nickel (Ni), tungsten (W), or an alloy thereof, among others. The gate electrode 132 and the first pad 134 may have a single-layered structure or a multiple-layered structure.

A first interlayer insulation layer 140 may be provided on the gate electrode 132 and the first pad 134 of the rigid portion A1. In the rigid portion A1, the first interlayer insulation layer 140 may cover and contact at least one side surface of each of the first buffer layer 110, the second buffer layer 120, and the gate insulation layer 130.

The first interlayer insulation layer 140 may be formed as a single layer or multiple layers of an inorganic insulating material. The inorganic insulating material of the first interlayer insulation layer 140 may include silicon nitride (SiNx), silicon oxide (SiOx), or silicon oxynitride (SiON), among others.

In order to prevent damage of the first interlayer insulation layer 140 such as cracks due to stretching, the first interlayer insulation layer 140 may be removed in the soft portion A2 or absent from the soft portion A2 to substantially correspond to the rigid portion A1. The first interlayer insulation layer 140 may be provided over only the first base portion 104a of the base substrate 104 and may not be provided over the second base portion 104b.

An auxiliary electrode 142 may be provided on the first interlayer insulation layer 140 of the rigid portion A1. The auxiliary electrode 142 may overlap the light blocking layer 112 and may be in contact with the light blocking layer 112 through a contact hole provided in the second buffer layer 120, the gate insulation layer 130, and the first interlayer insulation layer 140. The auxiliary electrode 142 may be spaced apart from the semiconductor layer 122, the gate electrode 132, and the first pad 134.

The auxiliary electrode 142 may be formed of a conductive material such as metal. For example, the auxiliary electrode 142 may be formed of at least one of aluminum (Al), copper (Cu), molybdenum (Mo), titanium (Ti), chromium (Cr), nickel (Ni), tungsten (W), or an alloy thereof, among others. The auxiliary electrode 142 may have a single-layered structure or a multiple-layered structure.

A second interlayer insulation layer 150 may be provided on the auxiliary electrode 142 of the rigid portion A1. The second interlayer insulation layer 150 may be formed as a single layer or multiple layers of an inorganic insulating material. The inorganic insulating material of the second interlayer insulation layer 150 may include silicon nitride (SiNx), silicon oxide (SiOx), or silicon oxynitride (SiON), among others.

In order to prevent damage of the second interlayer insulation layer 150 such as cracks due to stretching, the second interlayer insulation layer 150 may be removed in the soft portion A2 or absent from the soft portion A2 to substantially correspond to the rigid portion A1. The second interlayer insulation layer 150 may be provided only over the first base portion 104a of the base substrate 104 and may not be provided over the second base portion 104b.

A source electrode 152, a drain electrode 154, a connection electrode 156, and a second pad 158, and the stretchable line 159 may be provided on the second interlayer insulation layer 150 of the rigid portion A1.

The source electrode 152 and the drain electrode 154 may be spaced apart from each other with the gate electrode 132 positioned therebetween and may be in contact with both ends of the semiconductor layer 122 through contact holes provided in the first and second interlayer insulation layers 140 and 150 and the gate insulation layer 130. In addition, the source electrode 152 may overlap the auxiliary electrode 142 and may be in contact with the auxiliary electrode 142 through a contact hole provided in the second interlayer insulation layer 150.

The semiconductor layer 122, the gate electrode 132, the source electrode 152, and the drain electrode 154 may collectively constitute a thin film transistor TR.

The connection electrode 156 may be spaced apart from the thin film transistor TR. The connection electrode 156 may overlap the first pad 134 and may be in contact with the first pad 134 through a contact hole provided in the first and second interlayer insulation layers 140 and 150.

The second pad 158 may be spaced apart from the thin film transistor TR and may be disposed to be adjacent to an edge of the rigid portion A1.

The stretchable line 159 may be connected to the second pad 158, and the stretchable line 159 may extend into and also be provided in the soft portion A2. Thus, the stretchable line 159 is in both the rigid portion A1 and the soft portion A2. The stretchable line 159 may be directly connected to the second pad 158 and may be formed as one body as a single, integral, unitary component. Alternatively, the stretchable line 159 may be a separate component electrically connected to the second pad 158 directly or through another component.

The stretchable line 159 may be in contact with a top surface 150T and a side surface 150S of the second interlayer insulation layer 150 in the rigid portion A1 and may also be in contact with a side surface 140S of the first interlayer insulation layer 140.

In addition, the stretchable line 159 may be in contact with the first buffer layer 110 in the soft portion A2. Alternatively, in the soft portion A2, when the first buffer layer 110 is completely removed, the stretchable line 159 may be in contact with the base substrate 104.

In other embodiments, the stretchable line 159 may be provided on a different layer from the second pad 158 to overlap the second pad 158, and the stretchable line 159 may be in contact with the second pad 158 through a contact hole.

The source electrode 152, the drain electrode 154, the connection electrode 156, the second pad 158, and the stretchable line 159 may be formed of a conductive material such as metal. For example, the source electrode 152, the drain electrode 154, the connection electrode 156, the second pad 158, and the stretchable line 159 may be formed of at least one of aluminum (Al), copper (Cu), molybdenum (Mo), titanium (Ti), chromium (Cr), nickel (Ni), tungsten (W), or an alloy thereof, among others. The source electrode 152, the drain electrode 154, the connection electrode 156, the second pad 158, and the stretchable line 159 may have a single-layered structure or a multiple-layered structure.

A passivation layer 160 may be provided on the source electrode 152, the drain electrode 154, the connection electrode 156, the second pad 158, and the stretchable line 159 of the rigid portion A1. The passivation layer 160 may be formed as a single layer or multiple layers of an inorganic insulating material. The inorganic insulating material of the passivation layer 160 may include silicon nitride (SiNx), silicon oxide (SiOx), or silicon oxynitride (SiON), among others.

In order to prevent damage of the passivation layer 160 such as cracks due to stretching, the passivation layer 160 may be removed in the soft portion A2 to substantially correspond to the rigid portion A1. The passivation layer 160 may be provided only over the first base portion 104a of the base substrate 104 and may not be provided over the second base portion 104b.

The passivation layer 160 may also be omitted in some embodiments.

A planarization layer 170 may be provided on the passivation layer 160. The planarization layer 170 may eliminate a step difference due to the layers thereunder and may have a substantially flat top surface 170T. The planarization layer 170 may be formed of an organic insulating material such as photosensitive acrylic polymer (photo acryl), among others.

In addition, the planarization layer 170 may be provided in the rigid portion A1 and may not be provided in the soft portion A2. Accordingly, the planarization layer 170 may be provided over only the first base portion 104a of the base substrate 104 and may not be provided over the second base portion 104b in some embodiments. In an embodiment, a side surface 170S of the planarization layer 170 generally defines a boundary or interface between the rigid portion A1 and the soft portion A2. Accordingly, the layers provided under the planarization layer 170 may be in the rigid portion A1 while those same layers are excluded or absent from the soft portion A2 with the exception of the first buffer layer 110 where the same is present in the soft portion A2. In one or more embodiments, any of the above layers in the rigid portion A1 may also be present in the soft portion A2 with appropriate modifications, such as a reduction in thickness and/or a change in material composition, among others and as needed, to reduce the potential for damage to the layers such as by cracking.

A first electrode 172 and a second electrode 174 may be provided on the planarization layer 170 of the rigid portion A1.

The first electrode 172 and the second electrode 174 may be formed of a conductive material such as metal. For example, the first electrode 172 and the second electrode 174 may be formed of at least one of aluminum (Al), copper (Cu), molybdenum (Mo), titanium (Ti), chromium (Cr), nickel (Ni), tungsten (W), or an alloy thereof, among others. The first electrode 172 and the second electrode 174 may have a single-layered structure or a multiple-layered structure.

The first electrode 172 may overlap the drain electrode 154 and may be in contact with the drain electrode 154 through a contact hole provided in the planarization layer 170 and the passivation layer 160. The second electrode 174 may overlap the connection electrode 156 and may be in contact with the connection electrode 156 through a contact hole provided in the planarization layer 170 and the passivation layer 160.

Meanwhile, although not shown in the figure, a bank layer may be further provided on the first electrode 172 and the second electrode 174 in the rigid portion A1. The bank layer may expose at least parts of the first electrode 172 and the second electrode 174.

An adhesive layer 180 may be provided on the first and second electrodes 172 and 174 of the rigid portion A1. The adhesive layer 180 may be an anisotropic conductive film (ACF) including an insulating base member and a plurality of conductive balls 182 dispersed in the insulating base member, among others.

When heat or pressure is applied to the adhesive layer 180, the conductive balls 182 may be electrically connected in an area where the heat or pressure is applied, so that the adhesive layer 180 may have a conductive property. In an area where the heat or pressure is not applied, the adhesive layer 180 may have an insulating property.

A light-emitting element 190 may be provided on the adhesive layer 180. The light-emitting element 190 may include a first element electrode 192 and a second element electrode 194.

Here, the first element electrode 192 may be a p-electrode, and the second element electrode 194 may be an n-electrode. The first element electrode 192 may be an anode, and the second element electrode 194 may be a cathode. However, embodiments of the present disclosure are not limited thereto.

Alternatively, in other embodiments, the first element electrode 192 may be an n-electrode, and the second element electrode 194 may be a p-electrode. In this case, the first element electrode 192 may be a cathode, and the second element electrode 194 may be an anode.

The light-emitting element 190 may be provided in the form of a micro light-emitting diode chip (micro LED chip or uLED chip) including the n-electrode, an n-type layer, an active layer, a p-type layer, and the p-electrode. The light-emitting element 190 may have a flip-chip structure in which the n-electrode and the p-electrode are provided on the same side (for example, a side facing the first substrate 101) and light is emitted through a side opposite to the side provided with the n-electrode and the p-electrode (for example, a side facing the second substrate 106).

However, embodiments of the present disclosure are not limited thereto. The light-emitting element 190 may have a lateral structure in which the n-electrode and the p-electrode are provided on the same side and light is emitted through the same side provided with the n-electrode and the p-electrode or may have a vertical structure in which the n-electrode and the p-electrode are provided on opposite sides, respectively.

The first element electrode 192 of the light-emitting element 190 may overlap the first electrode 172, and the second element electrode 194 of the light-emitting element 190 may overlap the second electrode 174. The first element electrode 192 may be electrically connected to the first electrode 172 through the conductive balls 182 of the adhesive layer 180, and the second element electrode 194 may be electrically connected to the second electrode 174 through the conductive balls 182 of the adhesive layer 180.

A second adhesive layer 108 may be provided on the light-emitting element 190 and the stretchable line 159, and the second substrate 106 may be disposed on the second adhesive layer 108.

The second adhesive layer 108 may attach the light-emitting element 190 and the stretchable line 159 with the second substrate 106. The second adhesive layer 108 may be formed of the same material as the first adhesive layer 102.

The second adhesive layer 108 may have substantially the same thickness as the first adhesive layer 102 in at least the rigid portion A1.

As described above, in the stretchable display device 20 according to one or more embodiments of the present disclosure, the plurality of link lines may be provided in the pad portion A3. Each of the plurality of the link line may include the high resistance link and the low resistance link, and the high resistance links and the low resistance links of the adjacent link lines may be configured differently. Accordingly, since the plurality of link lines may have the uniform resistance, the uniform signal may be transmitted, thereby realizing the uniform image quality by compensating the resistance deviation.

In some stretchable displays, the pad portion of a stretchable display may not be stretched, and the boundary between the pad portion and the soft portion of the display area DA may be weak in mechanical durability.

Specifically, in the pad portion connected to the soft portion of the display area DA, specifically, in the first pad portion, there may be a relatively large island-shaped rigid pattern. Since the rigid pattern is formed of the same rigid material as the base substrate, when attaching the first substrate that is the flexible substrate and patterning the base substrate, cracks may occur at the boundary between the first pad portion where the rigid material is not patterned and the soft portion of the display area where the rigid material is patterned. Since the signal cannot be smoothly transmitted to each sub-pixel due to the cracks, defects such as dark lines may appear on the screen.

The occurrence of cracks can be minimized by attaching a protection member such as a polyimide tape to the boundary between the first pad portion and the soft portion, but this may increase the manufacturing process and costs and is therefore less desirable.

Accordingly, in the stretchable display device according to one or more embodiments of the present disclosure, by configuring the link line as a stretchable link line including at least one curved part, the occurrence of cracks can be prevented without the use of polyimide tape and associated increases in difficulty of manufacturing and cost.

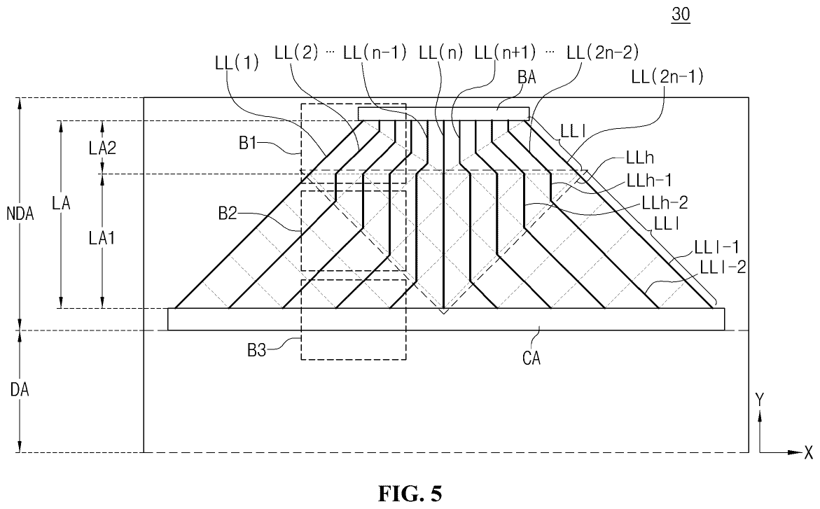

Such a stretchable display device according to one or more embodiments of the present disclosure will be described with reference to FIGS. 5 to 8.

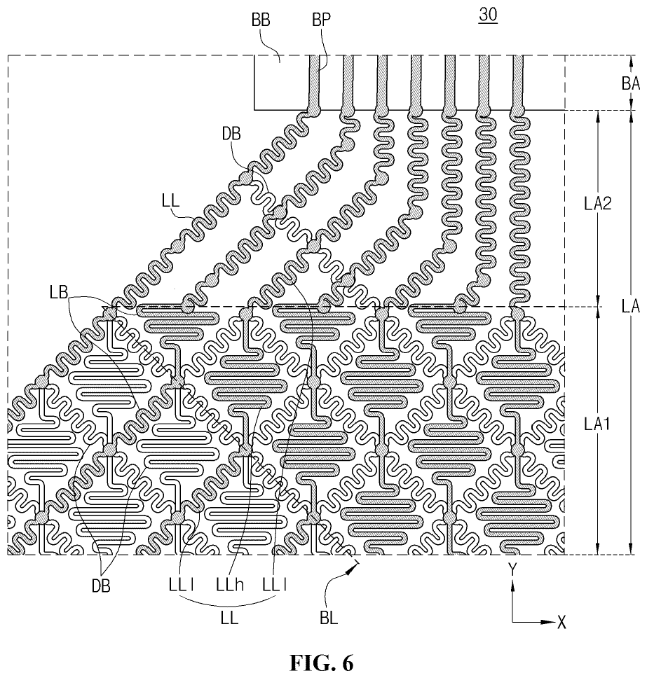

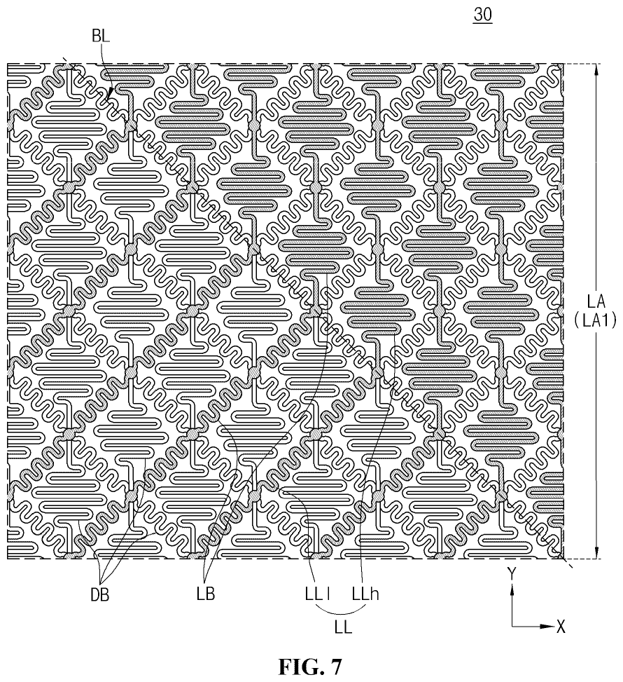

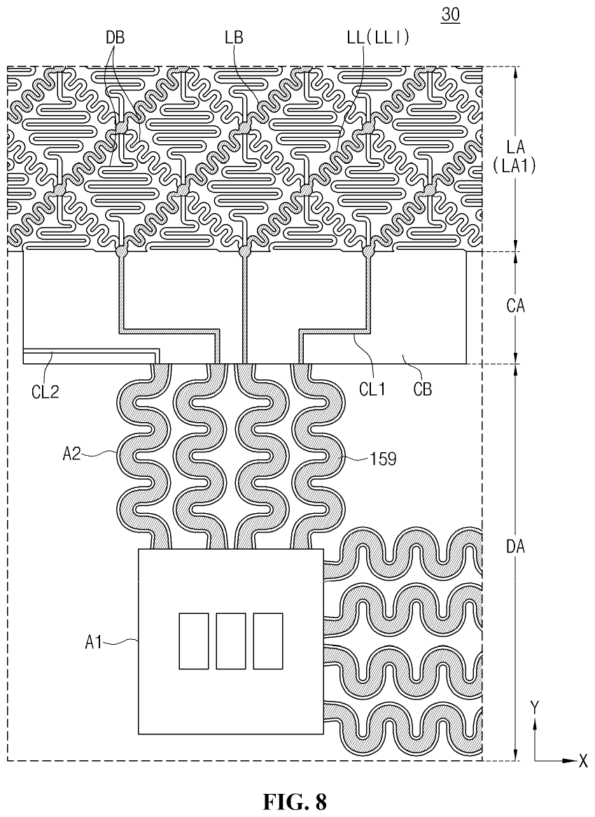

FIG. 5 is a schematic plan view of a stretchable display device 30 according to one or more embodiments of the present disclosure and shows a non-display area and a part of a display area of the display device. FIG. 6 is an enlarged view of area B1 of FIG. 5, FIG. 7 is an enlarged view of area B2 of FIG. 5, and FIG. 8 is an enlarged view of area B3 of FIG. 5.

As shown in FIGS. 5 to 8, a link area LA, a connection area CA, and a bonding area BA may be provided in the non-display area NDA. In the second direction Y, the link area LA may be disposed between the connection area CA and the bonding area BA, and the connection area CA may be disposed between the display area DA and link area LA. Accordingly, in successive order, the display 30 may have a structure of a display area DA, a connection area CA, a link area LA, and a bonding area BA. Each of the areas may also be regions or portions of the display 30.

A plurality of link lines LL may be provided in the link area LA. A plurality of first connection lines CL1 for connecting the link lines LL and the stretchable lines 159 of the soft portion A2 of the display area DA may be provided in the connection area CA. A plurality of bonding pads BP for connecting the link lines LL and the driver IC chip may be provided in the bonding area BA.

In the connection area CA, and with reference to FIG. 8, the plurality of first connection lines CL1 may be provided on a connection base CB. For example, three first connection lines CL1 may be provided on one connection base CB or a connection substrate CB. The connection base CB may be plural, and the plurality of connection bases CB may be spaced apart from each other in the first direction X. The connection base CB may also be singular. The connection base CB may be a single layer or a plurality of layers in a multi-layer stack.

In addition, one second connection line CL2 may be further provided on the connection base CB. The second connection line CL2 may transmit a constant voltage signal. For example, the second connection line CL2 may transmit a reference voltage, but embodiments of the present disclosure are not limited thereto. The second connection line CL2 may be provided on the same or a different layer from the first connection line CL1 and may be connected to another second connection line CL2 provided on another successive connection base CB adjacent thereto in the first direction X.

The first and second connection lines CL1 and CL2 may be connected to respective stretchable lines 159 provided in the soft portion A2 of the display area DA.

Next, in the bonding area BA, and with reference to FIG. 6, the plurality of bonding pads BP may be provided on one bonding base BB or a bonding substrate BB. The plurality of bonding pads BP may be spaced apart from each other in the first direction X. A distance between adjacent or successive bonding pads BP may be smaller than a distance between adjacent first connection lines CL1 in the connection area CA.

The bonding pads BP may be connected to pads of the driver IC chip to receive signals for displaying an image.

Meanwhile, with reference to FIGS. 6-8, the link area LA may include the first link area LA1 and a second link area LA2. The first link area LA1 may be disposed between the display area DA and the second link area LA2. Accordingly, the first link area LA1 may be disposed between the connection area CA and the second link area LA2, and the second link area LA2 may be disposed between the first link area LA1 and the bonding area BA.

The plurality of link lines LL provided in the link area LA may include high resistance links LLh and low resistance links LLl. Here, in the first link area LA1, the high resistance link LLh and the low resistance link LLl may be provided. In the second link area LA2, the low resistance link LLl may be provided, and the high resistance link LLh may not be provided.

As described above, one of the challenges of stretchable displays is that the distance between adjacent bonding pads provided in the bonding area may be different from a distance between adjacent pixels provided in the rigid portions of the display area. A length of the link line connecting the bonding pad and the pixel may vary depending on the location. Thus, a difference in resistance may occur between the link lines, which distorts image quality.

Accordingly, in the present disclosure, by differently configuring the high resistance links LLh and the low resistance links LLl of the adjacent link lines LL, the resistance of the link lines LL may be made uniform. That is, the adjacent link lines LL may include the high resistance links LLh and the low resistance links LLl of different lengths. As is well known, the resistance of a given material is directly proportional to its length, meaning that a shorter length of a material will have a lower resistance than a longer length of the same material where the two pieces of material have identical characteristics other than length. Thus, the use of “high” and “low” to describe the links or link lines generally refers to a length of the links and is measured relative to each other. For example, a high resistance link LLh may generally refer to a link that is longer than other low resistance links LLl.

Here, from the outermost area to the central area in the first direction X, the high resistance link LLh of the link line LL may become longer and the low resistance link LLl of the link line LL may become shorter. At this time, the link line LL at the outermost area may include only the low resistance link LLl. That is, at least one of the plurality of link lines LL may include the high resistance link LLh and the low resistance link LLl, and at least another of the plurality of link lines LL may include the low resistance link LLl and may not include the high resistance link LLh.

Specifically, the number of link lines LL may be 2n (n is an integer greater than 1) or (2n−1). In the embodiment of the present disclosure, the case where (2n−1) link lines are provided will be described as an example.

Here, each of the first link line LL(1) and the (2n−1)th link line LL(2n−1), which are provided at the outermost area of the display 30, may include only the low resistance link LLl and may not include the high resistance link LLh.

In addition, the link lines LL between the outermost link lines LL(1) and LL(2n−1) and the central link line LL(n), that is, second link line LL2 to (n−1)th link line LL(n−1) and (n+1)th link line LL(n+1) to (2n−2)th link line LL(2n−2) may include the high resistance link LLh and the low resistance link LLl, and the high resistance link LLh may be disposed between parts of the low resistance links LLl, as best illustrated in FIG. 5.

The adjacent link lines LL may include the high resistance links LLh of different lengths and the low resistance links LLl of different lengths, respectively. For example, the length of the high resistance link LLh of a kth link line LL(k is an integer greater than 0 and smaller than n) may be shorter than the length of the high resistance link LLh of a (k+1)th link line LL(k+1). In addition, the length of the low resistance link LLl of the kth link line LL(k) may be longer than the length of the low resistance link LLl of the (k+1)th link line LL(k+1).

The link lines LL may be disposed symmetrically along the first direction X with respect to the nth link line LL(n) of the central area. Alternatively, when 2n link lines LL may be provided, the link lines LL may be disposed symmetrically along the first direction X with respect to the nth link line LL(n) and the (n+1)th link line LL(n+1).

FIG. 5 schematically illustrates that in some embodiments, the display 30 may include the high resistance link lines LLh in only part of the link area LA that is represented schematically by the dashed triangle with the reference LLh. The regions of the link area LA surrounding the dashed triangle include only the low resistance link lines LLl. Generally speaking, the length of the link lines LL(which includes both the high and low resistance links LLh, LLl) changes in the direction X of the display 30. For example, the outermost link lines LL are generally longer than the link lines LL toward the center of the display 30. However, because the high resistance links LLh are only provided in a region of the link area AA, the length of the high and low resistance links LLh, LLl changes in a different manner from each other across the display 30.

From the outermost area of the display 30 to the central area in the direction X, the high resistance links LLh become longer. This is best illustrated by first high resistance link LLh−1 and successive second high resistance link LLh−2. As is shown in FIG. 5, the first high resistance link LLh−1, which is toward the outermost area of the display 30 in the direction X, is shorter than the second high resistance link LLh−2, which is closer to the center of the display 30 than the first high resistance link LLh−1. In other words, the high resistance link LLh−2 closer to the center is longer than the high resistance link LLh−1 that is further from the center of the display 30. FIG. 5 illustrates the display 30 at a large scale where the individual links are not visible. Thus, for purposes of illustration only, in FIG. 5, the length of the first and second high resistance links LLh−1, LLh−2 is bounded or defined by the dashed triangle marked LLh where the high resistance links LLh are generally present in the display 30. In reality, the illustrated link lines LL include a large number of smaller high resistance links, such as successive chains of high resistance links. Each of the individual links in the successive chains forming the link lines LL may have the same length with a number of links in the chain increasing to increase the length of the entire link lines LL shown in FIG. 5, or the number of individual links in each link line LL may be the same and the individual links in the chain may have a length that varies depending on the location of the link line LL to vary a total length of the link lines LL shown in FIG. 5.

The low resistance links LLl have an opposite arrangement to the high resistance links LLh, namely that they become shorter from the outer area of the display 30 toward the center of the display 30. For example, first low resistance link LLl-1, which is toward the outermost area of the display 30 in the direction X, is longer than a second low resistance link LLl-2, which is toward the center of the display 30 in FIG. 5. Thus, the low resistance link LLl-2 closer to the center is shorter than the low resistance link LL-2 that is toward the outermost area of the display 30. The length of the low resistance links LLl is illustrated schematically in FIG. 5 in a similar manner to the high resistance links LLh described above, which is to say that in practice, each illustrated link line LL in areas that include only low resistance links LLl may be composed of many smaller component parts.

The outermost link lines LL of FIG. 5 and the central link line LL(n) may include only the low resistance links LLl while the remaining link lines LL generally include at least some portion of the link line LL including the high resistance links LLh and the low resistance links LLl. The amount or number of high resistance links LLh, as well as a proportion of a given link line LL that includes high resistance links LLh relative to a portion that includes only low resistance links LLl may increase from an outer area of the display 30 toward the center of the display 30 as represented by dashed triangle LLh in FIG. 5 with its vertex toward the center of the display 30. The regions marked LLl in FIG. 5 correspond to areas with only low-resistance links LLl while the regions marked LLh correspond to areas with only high-resistance links LLh. As described further below, each of the link lines LL may also include a mixture of active low resistance links LLl and dummy high resistance links or a mixture of active high resistance links LLh and dummy low resistance links.

Returning to FIG. 6, the link line LL may be provided on a link base LB or link substrate LB. The link base LB may have substantially the same shape as the link line LL.

Additionally, in the first link area LA1, a dummy base DB or dummy substrate DB may be provided between the adjacent link lines LL. The dummy base DB may be connected to the link base LB and may be provided as one body.

Meanwhile, as shown in FIG. 6, in the second link area LA2, a dummy base DB may also be provided between the adjacent link lines LL, if necessary.

The link line LL, the link base LB, and the dummy base DB will be described in detail later. In FIGS. 6-8, the dashed line BL corresponds to the dashed line LLh in FIG. 5 to illustrate a boundary where the link lines LL do or do not include active high resistance links LLh.

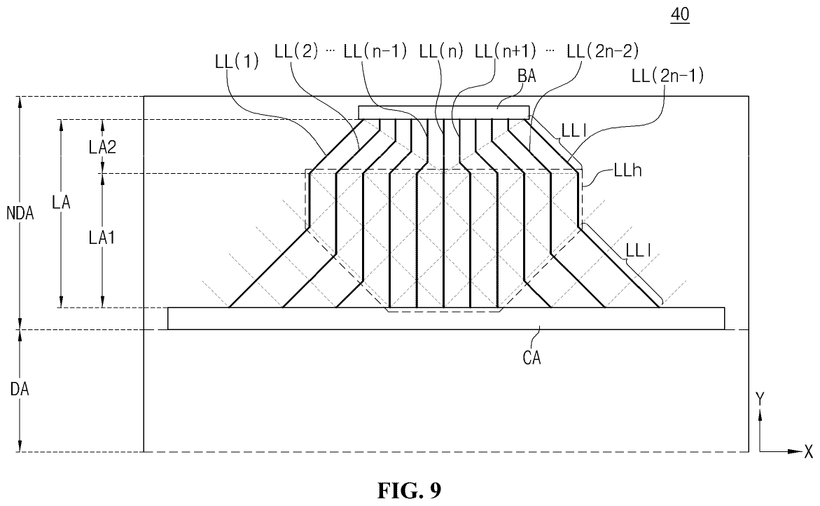

In other embodiments of the present disclosure, all link lines LL may include the high resistance link LLh and the low resistance link LLl. Another example of a stretchable display device according to another embodiment of the present disclosure will be described in detail with reference to FIG. 9.

FIG. 9 is a schematic plan view of another example of a stretchable display device 40 according to another embodiment of the present disclosure and shows a non-display area and a part of a display area.

As shown in FIG. 9, unlike the stretchable display device of FIG. 5, each of the first link line LLl and the (2n−1)th link line LL(2n−1) may also include the high resistance link LLh as well as the low resistance link LLl. In this case, the high resistance link LLh of each of the first link line LLl and the (2n−1)th link line LL(2n−1) may be disposed between parts of the low resistance links LLl.

Accordingly, all link lines LL may include the high resistance link LLh and the low resistance link LLl. At this time, from the outermost area to the central area in the first direction X, that is, from the first link line LLl and the (2n−1)th link line LL(2n−1) to the nth link line LL(n), the high resistance link LLh may become longer and the low resistance link LLl may become shorter.

Each of the high resistance link LLh and the low resistance link LLl may include at least one unit structure, and the length of each of the high resistance link LLh and the low resistance link LLl may be proportional to the number of unit structures included therein.

Meanwhile, as shown in FIG. 6, at least one link line LL may include a part of the high resistance link LLh.

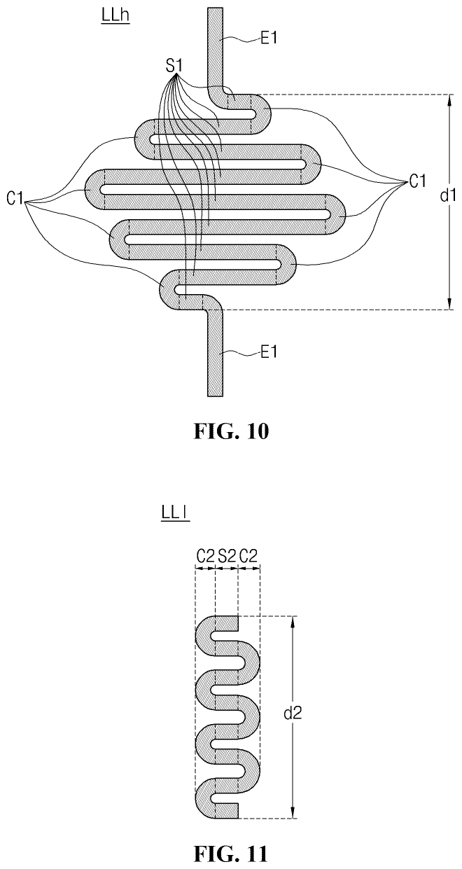

The unit structures of the high resistance link LLh and the low resistance link LLl will be described in detail with reference to FIG. 10 and FIG. 11, meaning that FIG. 10 and FIG. 11 provide more detail of the component parts of the link lines LL or the high resistance links LLh and the low resistance links LLl.

FIG. 10 is a schematic view of a unit structure of a high resistance link LLh of a link line LL according to one or more embodiments of the present disclosure, and FIG. 11 is a schematic view of a unit structure of a low resistance link LLl of a link line LL according to one or more embodiments of the present disclosure.

In FIG. 10 and FIG. 11, each of the high resistance link LLh and the low resistance link LLl of the link line LL may include at least one curved part and at least one straight part and may have a wave structure substantially including a plurality of wave shapes.

The ratio of length to straight line of the high resistance link LLh may be greater than the ratio of length to straight line of the low resistance link LLl. The ratio of length to straight line is a value calculated by dividing a total length of the line (i.e., a total length of the unfolded line) by a straight distance between both ends of the line (i.e., of a folded line). As the ratio of length to straight line increases, the resistance of the line may increase given the increase in the straight length. That is, the resistance of the high resistance link LLh may be higher than the resistance of the low resistance link LLl.

Specifically, the high resistance link LLh of FIG. 10 may include a plurality of first straight parts S1 and a plurality of first curved parts C1 connecting the plurality of first straight parts S1. The plurality of first straight parts S1 may have different lengths. In an embodiment, and as shown in FIG. 10, the first straight parts S1 increase in length from one side or outer end of the high resistance link LLh toward the center of the link LLh before decreasing again toward the other side or outer end. Thus, outer straight parts S1 may have a shorter or shortest length and a straight part S1 at the center of the link LLh may have a longer or longest length relative to the other first straight parts S1. In addition, the high resistance link LLh may further include an extension part E1 at each of its both ends. In an embodiment, the extension part E1 is an outermost end of the link LLh that extends in a direction generally perpendicular to the direction of the straight parts. Each extension part E1 may be aligned or offset relative to a vertical axis through a center of the link LLh. Many other configurations of the high resistance links LLh are contemplated, including at least that the straight parts S1 all have the same length, or a different arrangement relative to each other. For example, the straight parts S1 may all increase in length in only one direction (i.e. toward either outer end), or may increase and decrease length several times across the link LLh. Thus, the disclosure is not limited to the example shown in FIG. 10.

The low resistance link LLl of FIG. 11 may include a plurality of second straight parts S2 and a plurality of second curved parts C2 connecting the plurality of second straight parts S2. The plurality of second straight parts S2 may have the same length and the plurality of second curved parts C2 may have the same radius of curvature such that the low resistance link LLl has a sine wave shape with repeated crests and troughs at a constant wavelength. In addition, although not shown in the figures, the low resistance link LLl may further include an extension part at each of its both ends.

Here the first curved part C1 and the second curved part C2 may have the same size and length and radius of curvature in some embodiments. As a result, the spacing between the first and second straight parts S1, S2 may generally be the same and constant across the links LLh, LLl. In some embodiments, the characteristics of the curved parts C1, C2 are different to vary the spacing between straight parts S1, S2. In addition, the length of the first straight part S1 may be equal to or greater than the length of the second straight part S2.

A first ratio of length to straight line, which is a value that a total length of the high resistance link LLh excluding the extension part E1 is divided by a first straight distance d1 corresponding thereto, may be greater than a second ratio of length to straight line, which is a value that a total length of the low resistance link LLl excluding the extension part is divided by a second straight distance d2 corresponding thereto. The ratio of length to straight line is calculated as noted above. For example, the ratio of length to straight line in FIG. 10 may be calculated by first determining the distance d1 of the high resistance link LLh between the extensions E1. The distance d1 may be a straight-line distance. Then, a total length of the high resistance link LLh in its folded shape is determined. The total length of the high resistance link LLh includes the length of all the straight parts S1 and curved parts C1 between the extensions E1. The total length is then divided by the distance d1 to determine the ratio of total length to straight line length with d1 generally referring to the straight line distance. In an embodiment, the high resistance links may have a total length including the straight parts S1 and curved parts C1 (i.e., a total straight length) between the extensions E1 that is greater than a total length of the low resistance links, again measured to include the straight and curved parts S2, C2 while excluding the extensions, and the ratio of length to straight line is also greater for the high resistance links LLh relative to the low resistance links LLl.

In some embodiments, the straight parts S1, S2 may also be referred to herein as respective straight regions, portions, sections, segments, areas, lines, components, aspects and the like. Similarly, the curved parts C1, C2 may also be referred to herein as respective curved regions, portions, sections, segments, areas, lines, components, aspects and the like.

Accordingly, the high resistance link LLh may have the higher resistance than the low resistance link LLl.

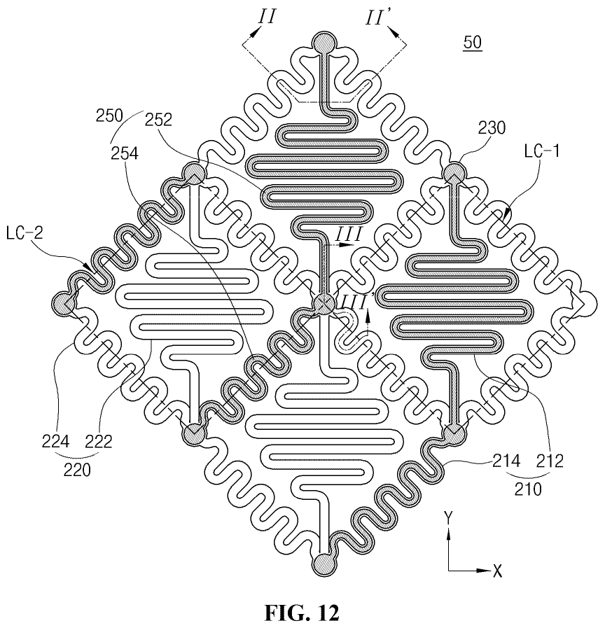

The plan and cross-sectional configuration of the link line LL including the high resistance link LLh and the low resistance link LLl will be described in detail with reference to FIGS. 12 to 14.

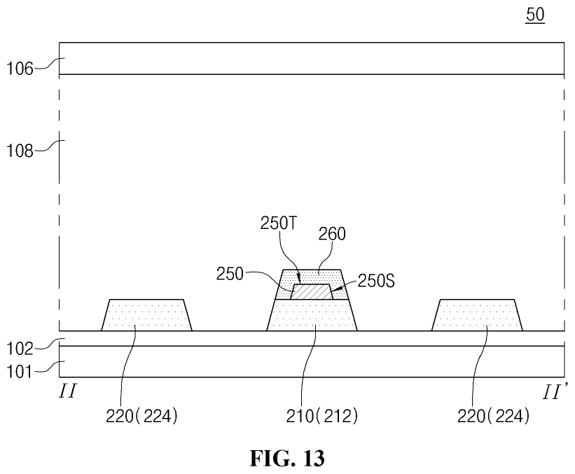

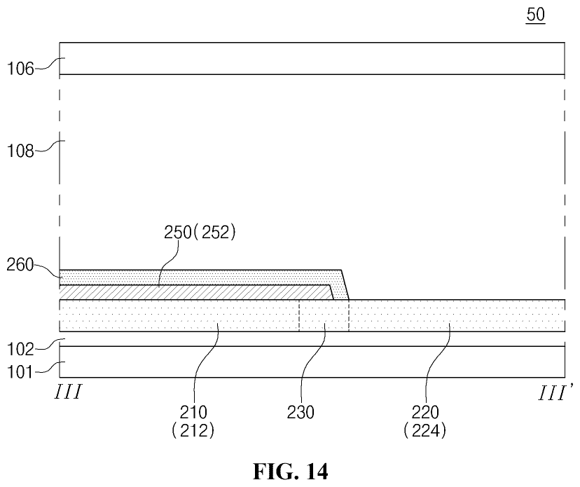

FIG. 12 is a schematic plan view enlarging a link area of a stretchable display area of a stretchable display 50 according to one or more embodiments of the present disclosure, FIG. 13 is a cross-sectional view corresponding to line II-II′ of FIG. 12, and FIG. 14 is a cross-sectional view corresponding to line III-III′ of FIG. 12.

In FIGS. 12 to 14, the link line 250 may include the high resistance link 252 and the low resistance link 254 and may be disposed on the link base 210. The dummy base 220 may be provided between the link bases 210 or link substrates 210.

Specifically, the first adhesive layer 102 may be provided on the first substrate 101, and the link base 210 and the dummy base 220 may be provided on the first adhesive layer 102. The link base 210 may include a first link base 212 and a second link base 214 which may also be link substrates 212, 214. The high resistance link 252 may be provided on the first link base 212, and the low resistance link 254 may be provided on the second link base 214. Accordingly, the high resistance link 252 may overlap the first link base 212, and the low resistance link 254 may overlap the second link base 214.

Here, the first link base 212 may have substantially the same shape as the high resistance link 252, and the second link base 214 may have substantially the same shape as the low resistance link 254. That is, each of the first link base 212 and the second link base 214 may have at least one curved part.

The dummy base 220 may be disposed between adjacent link bases 210. The dummy base 220 may include a first dummy base 222 and a second dummy base 224. The first dummy base 222 may have substantially the same shape as the first link base 212, and the second dummy base 224 may have substantially the same shape as the second link base 214.

The first and second link bases 212 and 214 and the first and second dummy bases 222 and 224 may be connected to each other to be provided as one body and may constitute a unit link to be repeatedly disposed. That is, the plurality of second link bases 214 and/or the plurality of second dummy bases 224 may be connected to each other to form a unit link, and the first link base 212 or the first dummy base 222 may be disposed in each unit link. For example, the unit link or link component LC may have a substantially rectangular or rhombus shape, and the first link base 212 or the first dummy base 222 may be disposed to extend along a diagonal direction of the rectangular shape or rhombus shape. The second dummy bases 224 may be interconnected to define a link component LC-1 shown in FIG. 12. One of the first link bases 212 is coupled to and/or connected to the link component LC-1 and extends through an open space in the middle of the link component LC-1. Except as otherwise noted, the “unit link” may refer to the link component LC shown in FIG. 12.

Specifically, two second link bases 214 and two second dummy bases 224 may be connected to each other to form one unit link or link component LC-2. The first dummy base 222 may be disposed in the corresponding unit link and may be connected to the two second link bases 214 and the two second dummy bases 224.

In addition, four second dummy bases 224 may be connected to each other to form one unit link. The first link base 212 may be disposed in the corresponding unit link and may be connected to the four second dummy bases 224.

Meanwhile, an auxiliary base 230 may be provided at each corner of the unit link having the rectangular shape or rhombus shape. That is, the auxiliary base 230 may be provided in an area where the first and second link bases 212 and 214 and the first and second dummy bases 222 and 224 are connected to each other.

For example, the auxiliary base 230 may have a circular shape or polygonal shape. However, embodiments of the present disclosure are not limited thereto. The shape of the auxiliary base 230 may vary.

The link base 210, the dummy base 220, and the auxiliary base 230 may be formed of the same material as the base substrate 104 provided in the display area DA. That is, the link base 210, the dummy base 220, and the auxiliary base 230 may be formed of a polyimide (PI) resin or epoxy resin, among others.

The link base 210 may serve to support and protect the link line 250. The dummy base 220 and the auxiliary base 230 may prevent damage of the link area LA due to repeated stretching, thereby improving the mechanical durability.

Next, the link line 250 may be provided on the link base 210. The link line 250 may not be provided on the dummy base 220. The link line 250 may include the high resistance link 252 and the low resistance link 254. The high resistance link 252 may be disposed on the first link base 212, and the low resistance link 254 may be disposed on the second link base 214.

The link line 250 may be formed of the same material and through the same process as the source and drain electrodes 152 and 154 provided in the rigid portion A1 of the display area DA. However, embodiments of the present disclosure are not limited thereto.

An insulation pattern 260 may be provided on the link line 250. That is, the insulation pattern 260 may be provided over the link base 210 and may not be provided over the dummy base 220. The insulation pattern 260 may be an inorganic layer. The insulation pattern 260 may be formed of the same material and through the same process as the passivation layer 160 provided in the rigid portion A1 of the display area DA. However, embodiments of the present disclosure are not limited thereto. The insulation pattern 260 may be provided to cover a top surface 250T and a side surface 250S or all side surfaces 250S of the link line 250 over the link base 210 and may extend and also be provided over the dummy base 220.

The insulation pattern 260 may be an organic layer. In this case, the insulation pattern 260 may be formed of the same material and through the same process as the planarization layer 170 provided in the rigid portion A1 of the display area EA.

Next, the second adhesive layer 108 may be provided on the insulation pattern 260 and the dummy base 220, and the second substrate 106 may be provided on the second adhesive layer 108. The second adhesive layer 108 may be in contact with first adhesive layer 102 between the insulation pattern 260 and the dummy base 220.

As described above, in the stretchable display device according to one or more embodiments of the present disclosure, the link line 250 may be configured as the stretchable link line including the high resistance link 252 and the low resistance link 254 with the different ratios of length to straight line, and the high resistance links 252 and the low resistance links 254 of the adjacent link lines 250 may be configured differently. Accordingly, the resistance of the link lines 250 may be made uniform, thereby implementing the uniform image quality. In addition, by designing the link area LA of the non-display area NDA occupying a relatively large area to be stretchable, the mechanical durability of the display panel 100 can be improved.

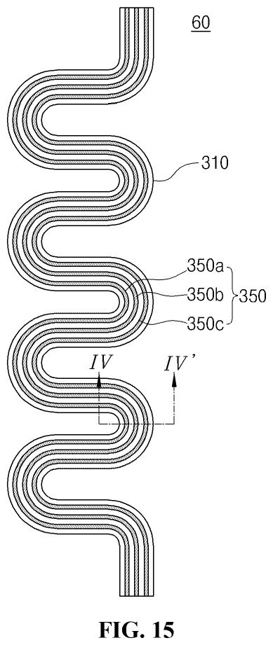

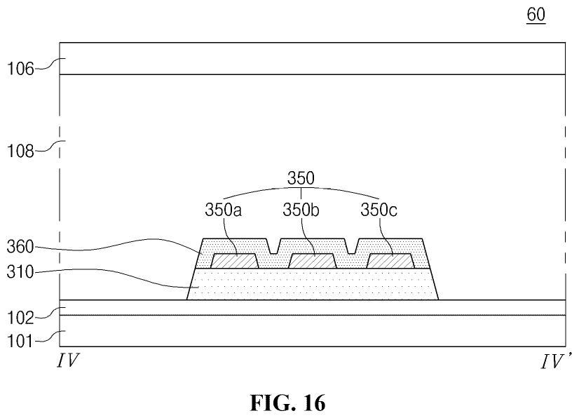

In the previous embodiment, the configuration in which one link line is provided on one link base has been described, but a plurality of link lines may be provided on one link base. Such a stretchable display device according to another embodiment of the present disclosure will be described in detail with reference to FIG. 15 and FIG. 16. The stretchable display device according to another embodiment of the present disclosure has substantially the same configuration as that of the previous embodiment, except for the link lines. The same parts as that of the previous embodiment are designated by the same or similar reference signs, and explanation for the same parts may be shortened or omitted.

FIG. 15 is a schematic plan view enlarging a link area of a stretchable display area of a stretchable display device 60 according to one or more embodiments of the present disclosure, and FIG. 16 is a cross-sectional view corresponding to line IV-IV′ of FIG. 15.

In FIG. 15 and FIG. 16, a plurality of link lines 350 may be provided on a link base 310, and an insulation pattern 360 may be provided on the plurality of link lines 350. For example, three link lines 350a, 350b, and 350c may be provided on one link base 310. The three link lines 350a, 350b, and 350c may correspond to a pixel provided in one rigid portion A1 of the display area DA and may transmit red, green, and blue data signals to first, second, third sub-pixels SP1, SP2, and SP3, respectively. Accordingly, a single link base 310 may support a plurality of link lines 350, and preferably all of the link lines 350 needed to drive three sub-pixels (i.e., red, blue, and green and/or white sub-pixels) on a rigid portion of a stretchable display.

In the stretchable display device 60 according to one or more embodiments of the present disclosure, the stretching properties can be improved by increasing the arrangement density of the link line 350. In addition, the pitch of the link lines 350, that is, the distance between the link lines 350 may be reduced, and there may be advantageous for high-resolution implementation.

In the present disclosure, by configuring the link line as the stretchable link line including the high resistance link and the low resistance link and by differently configuring the high resistance links and the low resistance links of the adjacent link lines, the resistance of the link lines 250 may be made uniform, and the uniform image quality may be implemented.

In addition, by designing the link area of the non-display area occupying a relatively large area to be stretchable, the mechanical durability of the display panel can be improved. Accordingly, by improving the lifetime, the production power consumption can be reduced to achieve the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure, and the scope of the appended claims is not limited by this disclosure.

In an embodiment, a stretchable display device may include: a first substrate including a display area and a non-display area; a plurality of rigid portions disposed on the first substrate in the display area, the plurality of rigid portions spaced apart from each other in a first direction and a second direction; a plurality of flexible portions provided between corresponding ones of the plurality of rigid portions; a link area in the non-display area of the first substrate; a plurality of link lines disposed on the first substrate in the link area; and a second substrate disposed on the first substrate, wherein a first link line of the plurality of link lines includes a high resistance link and a low resistance link, wherein each of the high resistance link and the low resistance link includes at least one curved part and at least one straight part, and wherein a ratio of length to straight line of the high resistance link is greater than a ratio of length to straight line of the low resistance link.

In an embodiment, the high resistance link includes a plurality of first straight parts, and the low resistance link includes a plurality of second straight parts, and the plurality of first straight parts have different lengths, and the plurality of second straight parts have a same length.

In an embodiment, the lengths of the plurality of first straight parts are equal to or greater than the length of the plurality of second straight parts.

In an embodiment, the link area includes a first link area and a second link area, and the first link area is disposed between the display area and the second link area, and the high resistance link is provided in the first link area.

In an embodiment, the low resistance link is provided in the first link area and the second link area.

In an embodiment, the low resistance link is one of a plurality of low resistance links of the first link line, and the high resistance link of the first link line is disposed between a first low resistance link of the plurality of low resistance links disposed in the first link area and a second low resistance link of the plurality of low resistance links disposed in the second link area.

In an embodiment, the high resistance link of the first link line is longer than a high resistance link of a second link line successive to the first link line, and the low resistance link of the first link line is shorter than a low resistance link of the second link line.

In an embodiment, a link base is provided under each of the plurality of link lines, and the link base includes a first link base corresponding to the high resistance link and a second link base corresponding to the low resistance link.

In an embodiment, a dummy base is provided between the link bases, and the dummy base is a single body coupled to the link bases.

In an embodiment, the dummy base includes a first dummy base having a same shape as the first link base and a second dummy base having a same shape as the second link base.

In an embodiment, four second dummy bases are connected to each other to form a link component, and the first link base is disposed in the link component and is connected to the four second dummy bases.

In an embodiment, two second link bases and two second dummy bases are connected to each other to form a link component, and the first dummy base is disposed in the link component and is connected to the two second link bases and the two second dummy bases.

In an embodiment, the stretchable display device further includes an auxiliary base disposed at a connection interface between the first and second link bases and the first and second dummy bases.

In an embodiment, multiple link lines of the plurality of link lines are provided on one link base and spaced apart from each other.

In an embodiment, the stretchable display device further includes: a pixel provided in each of the plurality of rigid portions and including a plurality of sub-pixels; and a stretchable line provided in the flexible portion and connecting successive pixels, wherein each of the plurality of sub-pixels includes a thin film transistor and a light-emitting element electrically connected to the thin film transistor, and wherein the stretchable line is formed of a same material as source and drain electrodes of the thin film transistor.

In an embodiment, the stretchable display device further includes an insulation pattern on the stretchable line.

In an embodiment, a stretchable display device may include: a substrate including a display area and a non-display area; and a plurality of link lines disposed on the substrate in the non-display area, wherein a first link line of the plurality of link lines includes a high resistance link a low resistance link connected to the high resistance link, and wherein the high resistance link has a total length that is greater than a total length of the low resistance link.

In an embodiment, the stretchable display device may further include: a plurality of rigid sections disposed on the substrate in the display area, the plurality of rigid sections arranged in a matrix of rows and columns; and a plurality of flexible lines connected between corresponding ones of the plurality of rigid sections.

In an embodiment, the substrate is a first substrate, the stretchable display device further comprising: a link area in the non-display area of the substrate, the plurality of link lines disposed in the link area; and a second substrate disposed on the first substrate, wherein each of the high resistance link and the low resistance link includes at least one curved part and at least one straight part.

In an embodiment, each of the high resistance link and the low resistance link includes at least one curved part and at least one straight part, the at least one straight part of the high resistance link being longer than the at least one straight part of the low resistance link.

In an embodiment, a ratio of length to straight line of the high resistance link is greater than a ratio of length to straight line of the low resistance link.

In an embodiment, the high resistance link of the first link line is longer than a high resistance link of a second link line successive to the first link line, and the low resistance link of the first link line is shorter than a low resistance link of the second link line.

In an embodiment, a stretchable display device may include: a substrate including a display area and a non-display area; and a plurality of link lines disposed on the substrate in the non-display area, wherein a first link line of the plurality of link lines includes a high resistance link a low resistance link connected to the high resistance link, wherein each of the high resistance link and the low resistance link includes at least one curved part and at least one straight part, and wherein the at least one straight part of the high resistance link is longer than the at least one straight part of the low resistance link.

In an embodiment, a ratio of length to straight line of the high resistance link is greater than a ratio of length to straight line of the low resistance link.

In an embodiment, the substrate is a first substrate, the stretchable display device further comprising: a plurality of rigid sections disposed on the substrate in the display area; a plurality of flexible lines connected between corresponding ones of the plurality of rigid sections; a link area in the non-display area of the substrate, the plurality of link lines disposed in the link area; and a second substrate disposed on the first substrate.

In an embodiment, the high resistance link of the first link line is longer than a high resistance link of a second link line successive to the first link line, and the low resistance link of the first link line is shorter than a low resistance link of the second link line.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A stretchable display device, comprising:
a first substrate including a display area and a non-display area;
a plurality of rigid portions disposed on the first substrate in the display area, the plurality of rigid portions spaced apart from each other in a first direction and a second direction;
a plurality of flexible portions provided between corresponding ones of the plurality of rigid portions;
a link area in the non-display area of the first substrate;
a plurality of link lines disposed on the first substrate in the link area; and
a second substrate disposed on the first substrate,
wherein a first link line of the plurality of link lines includes a high resistance link and a low resistance link,
wherein a ratio of length to straight line of the high resistance link is greater than a ratio of length to straight line of the low resistance link.

2. The stretchable display device of claim 1, wherein each of the high resistance link and the low resistance link includes at least one curved part and at least one straight part.

3. The stretchable display device of claim 1, wherein the high resistance link includes a plurality of first straight parts, and the low resistance link includes a plurality of second straight parts, and
wherein the plurality of first straight parts have different lengths, and the plurality of second straight parts have a same length.

4. The stretchable display device of claim 3, wherein the lengths of the plurality of first straight parts are equal to or greater than the length of the plurality of second straight parts.

5. The stretchable display device of claim 1, wherein the link area includes a first link area and a second link area, and the first link area is disposed between the display area and the second link area, and
wherein the high resistance link is provided in the first link area.

6. The stretchable display device of claim 5, wherein the low resistance link is provided in the first link area and the second link area.

7. The stretchable display device of claim 6, wherein the low resistance link is one of a plurality of low resistance links of the first link line, and
wherein the high resistance link of the first link line is disposed between a first low resistance link of the plurality of low resistance links disposed in the first link area and a second low resistance link of the plurality of low resistance links disposed in the second link area.

8. The stretchable display device of claim 1, wherein the high resistance link of the first link line is longer than a high resistance link of a second link line successive to the first link line, and the low resistance link of the first link line is shorter than a low resistance link of the second link line.

9. The stretchable display device of claim 1, wherein a link base is provided under each of the plurality of link lines, and the link base includes a first link base corresponding to the high resistance link and a second link base corresponding to the low resistance link.

10. The stretchable display device of claim 9, wherein a dummy base is provided between the link bases, and the dummy base is a single body coupled to the link bases.

11. The stretchable display device of claim 10, wherein the dummy base includes a first dummy base having a same shape as the first link base and a second dummy base having a same shape as the second link base.

12. The stretchable display device of claim 11, wherein four second dummy bases are connected to each other to form a link component, and
wherein the first link base is disposed in the link component and is connected to the four second dummy bases.

13. The stretchable display device of claim 11, wherein two second link bases and two second dummy bases are connected to each other to form a link component, and
wherein the first dummy base is disposed in the link component and is connected to the two second link bases and the two second dummy bases.

14. The stretchable display device of claim 11, further comprising:
an auxiliary base disposed at a connection interface between the first and second link bases and the first and second dummy bases.

15. The stretchable display device of claim 9, wherein multiple link lines of the plurality of link lines are provided on one link base and spaced apart from each other.

16. The stretchable display device of claim 1, further comprising:
a pixel provided in each of the plurality of rigid portions and including a plurality of sub-pixels; and
a stretchable line provided in the flexible portion and connecting successive pixels,
wherein each of the plurality of sub-pixels includes a thin film transistor and a light-emitting element electrically connected to the thin film transistor, and
wherein the stretchable line is formed of a same material as source and drain electrodes of the thin film transistor.

17. The stretchable display device of claim 16, further comprising an insulation pattern on the stretchable line.

18. A stretchable display device, comprising:
a substrate including a display area and a non-display area; and
a plurality of link lines disposed on the substrate in the non-display area,
wherein a first link line of the plurality of link lines includes a high resistance link and a low resistance link connected to the high resistance link, and
wherein the high resistance link has a total length that is greater than a total length of the low resistance link.

19. The stretchable display device of claim 18, further comprising:
a plurality of rigid sections disposed on the substrate in the display area, the plurality of rigid sections arranged in a matrix of rows and columns; and
a plurality of flexible lines connected between corresponding ones of the plurality of rigid sections.

20. The stretchable display device of claim 19, wherein the substrate is a first substrate, the stretchable display device further comprising:
a link area in the non-display area of the substrate, the plurality of link lines disposed in the link area; and
a second substrate disposed on the first substrate, wherein each of the high resistance link and the low resistance link includes at least one curved part and at least one straight part.

21. The stretchable display device of claim 18, wherein each of the high resistance link and the low resistance link includes at least one curved part and at least one straight part, the at least one straight part of the high resistance link being longer than the at least one straight part of the low resistance link.

22. The stretchable display device of claim 18, wherein a ratio of length to straight line of the high resistance link is greater than a ratio of length to straight line of the low resistance link.

23. A stretchable display device, comprising:
a substrate including a display area and a non-display area; and
a plurality of link lines disposed on the substrate in the non-display area,
wherein a first link line of the plurality of link lines includes a high resistance link and a low resistance link connected to the high resistance link,
wherein each of the high resistance link and the low resistance link includes at least one curved part and at least one straight part, and
wherein the at least one straight part of the high resistance link is longer than the at least one straight part of the low resistance link.

24. The stretchable display device of claim 23, wherein a ratio of length to straight line of the high resistance link is greater than a ratio of length to straight line of the low resistance link.

25. The stretchable display device of claim 23, wherein the substrate is a first substrate, the stretchable display device further comprising:
a plurality of rigid sections disposed on the substrate in the display area;
a plurality of flexible lines connected between corresponding ones of the plurality of rigid sections;
a link area in the non-display area of the substrate, the plurality of link lines disposed in the link area; and
a second substrate disposed on the first substrate.
